(19) United States
(12) Patent Application Publication
(10) Pub. No.: US 2023/0420276 A1
(43) Pub. Date: Dec. 28, 2023

(54) INTEGRATED BENCHTOP SEMICONDUCTOR PROCESSING CELLS AND SEMICONDUCTOR FABS FORMED FROM SUCH CELLS AND SEMICONDUCTOR TOOL LIBRARIES

(71) Applicant: Inchfab, Inc., Sunnyvale, CA (US)

(72) Inventors: Mitchell David Hsing, Saratoga, CA (US); Parker Andrew Gould, Berkeley, CA (US)

(73) Assignee: Inchfab, Inc., Sunnyvale, CA (US)

(21) Appl. No.: 18/343,301

(22) Filed: Jun. 28, 2023

Related U.S. Application Data
(60) Provisional application No. 63/367,156, filed on Jun. 28, 2022.

(51) Int. Cl. H01L 21/67

(52) U.S. Cl. CPC H01L 21/6719

(57) ABSTRACT

Described herein are integrated benchtop semiconductor process cells and cell-based semiconductor fabs. A cell includes a tool compartment in which one or more semiconductor process tools are positioned. Each process tool is modular and assembled from units that define the tool configuration and functionality. The cell also comprises one or more support modules fluidically coupled to the semiconductor process tools and external connections. As such, a cell can be operable as a standalone unit with minimal external connections, it can be integrated with one or more additional cells to form a cell-based semiconductor fab. A cell can have a minimal footprint (e.g., less than 2-3 square meters) while supporting one or more tools (e.g., four different tools). As such, an entire semiconductor fab can be formed with minimal facility requirements (e.g., space, power) to produce low-volume devices. Also provided are semiconductor tool libraries for such purposes.

### CROSS-REFERENCE TO RELATED APPLICATIONS

This application claims the benefit under 35 U.S.C. § 119(e) of U.S. Provisional Patent Application 63/367,156, filed on 2022 Jun. 28, which is incorporated herein by reference in its entirety for all purposes.

### BACKGROUND

Conventional semiconductor processing equipment is quite complex and expensive. This equipment is typically used in semiconductor fabrication plants, which are commonly referred to as semiconductor foundries or fabs. A typical semiconductor fab includes multiple different semiconductor process tools that are arranged to manufacture various semiconductor devices, such as integrated circuits. A typical fab can cost over $1 billion, which is acceptable and even desirable for high-volume high-margin integrated circuits (e.g., memory devices, central processing units, and the like). However, this cost and complexity present a major obstacle to microfabricated devices outside of mainstream semiconductor devices, such as microelectromechanical systems (MEMS) sensors. The current semiconductor fabrication paradigm requires the fabrication of devices in extremely high volumes to justify the high capital investment. This often presents a challenge as the ratio of investment to market demand in terms of volume and size is unjustifiable. The high barrier of entry incurred from the high capital investment ultimately prevents new technologies from reaching realization, these technologies often fall in the category of microelectromechanical systems (MEMS) sensors.

What is needed are new tools and systems capable of cost-efficient manufacturing of lower-volume devices, e.g. MEMS sensors and other types of integrated circuits.

### SUMMARY

Described herein are integrated benchtop semiconductor process cells and cell-based semiconductor fabs. A cell includes a tool compartment in which one or more semiconductor process tools are positioned. Each process tool is modular and assembled from units that define the tool configuration and functionality. The cell also comprises one or more support modules fluidically coupled to the semiconductor process tools and external connections. As such, a cell can be operable as a standalone unit with minimal external connections, it can be integrated with one or more additional cells to form a cell-based semiconductor fab. A cell can have a minimal footprint (e.g., less than 2-3 square meters) while supporting one or more tools (e.g., four different tools). As such, an entire semiconductor fab can be formed with minimal facility requirements (e.g., space, power) to produce low-volume devices. Also provided are semiconductor tool libraries for configuring specific cells and fabs.

In some examples, an integrated benchtop semiconductor process cell for processing a semiconductor substrate is provided. The integrated benchtop semiconductor process cell comprises a tool compartment, one or more semiconductor process tools, one or more support modules, and external connections. The tool compartment comprises a benchtop (e.g., with the height selected for the standing/sitting operator position). The one or more semiconductor process tools are positioned in the tool compartment on the benchtop. Each of the one or more semiconductor process tools is selected from the group consisting of a lithography tool, a photoresist process tool, a thermal process tool, a chemical vapor deposition tool, a sputtering tool, an atomic layer deposition tool, an ion-etching tool, and a wafer cutting tool. The one or more support modules are fluidically coupled to each of the one or more semiconductor process tools, and all are positioned under the benchtop. The one or more support modules comprise one or more selected from the group consisting of a vacuum pump, a water chiller, and a gas storage. The external connections are selected from the group consisting of an exhaust connection, an electrical power connection, and a compressed-gas connection. A combination of only three or less of the external connections and the one or more support modules is configured to support all operations of each of the one or more semiconductor process tools of the integrated benchtop semiconductor process cell. In other words, no additional power or material supply connections are needed for the operation of these tools.

In some examples, the integrated benchtop semiconductor process cell has a footprint of less than 3 square meters or less than 2 square meters. Even with such a small footprint, the integrated benchtop semiconductor process cell can accommodate multiple semiconductor process tools, e.g., two, three, four, or more tools in a single integrated benchtop semiconductor process.

In some examples, the one or more support modules comprise a compressor for supplying compressed gas to the one or more semiconductor process tools. As such, no external supply of compressed air is needed for the operation of the semiconductor process tools.

In some examples, the integrated benchtop semiconductor process cell uses only two or less of the external connections for supporting all operations of least one of the one or more semiconductor process tools. For example, these two or less of the external connections comprise or consist of the exhaust connection and the electrical power connection.

In some examples, the gas storage comprises all processing gases needed for operation of the one or more semiconductor process tools. For example, the gas storage comprises one or more gas storage containers. In the same or other examples, the integrated benchtop semiconductor process cell has a maximum power consumption of less than 100 kW.

In some examples, the integrated benchtop semiconductor process cell further comprises a plurality of controllers, positioned proximate to the one or more semiconductor process tools. The plurality of controllers comprises one or more mass flow controllers fluidically coupling the one or more semiconductor process tools to the gas storage. In some examples, the plurality of controllers further comprises one or more RF impedance matcher for one or more of a DC power supply, an RF power supply, a phase shifter, and a heater supply.

In the same or other examples, the integrated benchtop semiconductor process cell further comprises one or more control modules, communicatively coupled to the plurality of controllers and comprising a set of instructions for operating the plurality of controllers. For example, some of the plurality of controllers are positioned above the benchtop and the semiconductor process tools.

In some examples, the integrated benchtop semiconductor process cell further comprises a filter unit configured to flow filtered air into the tool compartment thereby reducing contamination in the tool compartment around the one or more semiconductor process tools. In the same or other examples, the tool compartment comprises a front opening for accessing the benchtop. In some examples, the tool compartment is enclosed and comprises a front panel comprising a plurality of gloves, isolating the benchtop from the environment. In these examples, the integrated benchtop semiconductor process cell comprises a substrate transfer module for isolated transfer between the tool compartment and the environment. In some examples, the semiconductor substrate has a diameter of less than 100 millimeters.

In some examples, each of the semiconductor process tools comprises a main module, a substrate transfer module, a processing module, and a substrate receiver module. The main module is sealably and removably coupled to each of the substrate transfer module, the processing module, and the substrate receiver module. The substrate transfer module is configured to protrude into the main module and position of the semiconductor substrate onto the substrate receiver module. The substrate receiver module is configured to lift the semiconductor substrate to an adjustable height in the processing module. In more specific examples, the main module of each of the semiconductor process tools is the same. The processing module of at least of the semiconductor process tools is different.

In some examples, the substrate receiver module is configured to perform at least one function selected from the group consisting of (a) applying heating or cooling to the semiconductor substrate, (b) flowing gas to the backside of the semiconductor substrate, (c) applying RF bias to the semiconductor substrate, and (d) measuring parameters on or near the substrate. In the same or other examples, each of the semiconductor process tools further comprises a flow control module fluidically coupled to the vacuum pump. In some examples, the substrate transfer module of each of the semiconductor process tools is fluidically coupled to the vacuum pump. In the same or other examples, the processing module of each of the semiconductor process tools is fluidically coupled to the gas storage.

In some examples, a cell-based semiconductor fab comprises an integrated benchtop semiconductor process cell and an additional integrated benchtop semiconductor process cell. Each of the integrated benchtop semiconductor process cell and the additional integrated benchtop semiconductor process cell comprises a tool compartment, one or more semiconductor process tools, and one or more support modules. The tool compartment comprises a benchtop. The one or more semiconductor process tools are positioned in the tool compartment on the benchtop. Each of the one or more semiconductor process tools is selected from the group consisting of a lithography tool, a photoresist process tool, a thermal process tool, a chemical vapor deposition tool, a sputtering tool, an atomic layer deposition tool, an ion-etching tool, and a wafer cutting tool. The one or more support modules are fluidically coupled to each of the one or more semiconductor process tools and positioned under the benchtop. The one or more support modules comprise one or more selected from the group consisting of a vacuum pump, a water chiller, and a gas storage. At least one of the one or more support modules of the integrated benchtop semiconductor process cell is fluidically coupled to at least one of the one or more semiconductor process tools of the additional integrated benchtop semiconductor process cell.

In some examples, at least one of the one or more support modules of the integrated benchtop semiconductor process cell, which is fluidically coupled to at least one of the one or more semiconductor process tools of the additional integrated benchtop semiconductor process cell, is a vacuum pump.

Provided also is a method of building a semiconductor fabrication line comprising semiconductor process tools and using a semiconductor tool library. In some examples, the method comprises determining a configuration of each of the semiconductor process tools, based on a corresponding one of semiconductor operations, selected for fabrication of a semiconductor device. The method also comprises selecting, from the semiconductor tool library, one of main modules, one of substrate transfer modules, one of processing modules, and one of substrate receiver modules for each of the semiconductor process tools and based on the configuration of each of the semiconductor process tools. Finally, the method comprises assembling each of the semiconductor process tools by connecting the one of main modules to the one of substrate transfer modules and the one of processing modules and also by positioning the one of substrate receiver modules inside the one of main modules, wherein the semiconductor process tools form the semiconductor fabrication line.

In some examples, the semiconductor operations are selected from the group consisting of lithography, photoresist processing, thermal processing, chemical vapor deposition, sputtering, atomic layer deposition, ion-etching, and wafer cutting.

In some examples, connecting the one of main modules to the one of substrate transfer modules and the one of processing modules comprises forming a sealed temporary connection between the one of main modules and each of the one of substrate transfer modules and the one of processing modules comprises. In the same or other examples, in the semiconductor tool library, each of the main modules is configured to connect to any one of the substrate transfer modules and, separately, to any one of the processing modules. In some examples, different ones of the processing modules are configured to perform different ones of the semiconductor operations. In the same or other examples, the semiconductor fabrication line comprises at least three of the semiconductor process tools having different configurations and configured to perform different ones of the semiconductor operations.

In some examples, the semiconductor fabrication line comprises an integrated benchtop semiconductor process cell comprising a tool compartment, one or more support modules, and external connections. In these examples, the method further comprises (a) positioning two or more of the semiconductor process tools on a benchtop of the tool compartment, (b) fluidically coupling the two or more the semiconductor process tools to the one or more support modules comprising one or more selected from the group consisting of a vacuum pump, a water chiller, and gas storage, and (c) connecting the two or more of the semiconductor process tools to the external connections selected from the group consisting of an exhaust connection, an electrical power connection, and a compressed-gas connection.

In some examples, the semiconductor tool library comprises multiple types of the main modules, multiple types of the substrate transfer modules, multiple types of the processing modules, and multiple types of the substrate receiver modules from the semiconductor processing library for each of the semiconductor process tools and based on the configuration of each of the semiconductor process tools. Any one of the main modules in the semiconductor tool library is configured to connect to any one of the substrate transfer modules and to any one of the processing modules and is further configured to receive any one of the substrate receiver modules.

In some examples, the method further comprises reconfiguring at least one of the semiconductor process tools by disconnecting the one of main modules from at least the one of processing modules and reconnecting a different one of processing modules to the one of main modules.

Also provided is a semiconductor tool library for building a semiconductor fabrication line for processing a semiconductor substrate. The semiconductor tool library comprises at least one type of main modules, at least one type of substrate transfer modules, multiple types of processing modules, and multiple types of substrate receiver modules. Any one of the main modules in the semiconductor tool library is configured to sealably couple to any one of the substrate transfer modules and to any one of the processing modules and is further configured to receive any one of the substrate receiver modules to form one of semiconductor process tools of the semiconductor fabrication line.

In some examples, each of the multiple types of the processing modules is selected from the group consisting of a lithography module, a photoresist processing module, a thermal processing module, a chemical vapor deposition module, a sputtering module, an atomic layer deposition module, an ion-etching module, and a wafer cutting module.

In some examples, at least one type of the main modules comprises multiple types of the main modules. In the same or other examples, at least one type of the main modules comprises multiple types of the substrate transfer modules. In some examples, the semiconductor substrate has a diameter of less than 100 millimeters. In the same or other examples, each of the semiconductor process tools has a footprint of less than 0.5 meters by 0.5 meters and has a height of up to 1.5 meters. In some examples, each of the semiconductor process tools has a weight of between 20 kg and 60 kg.

In some examples, the semiconductor tool library further comprises at least one type of flow control modules. Any one of the main modules in the semiconductor tool library is configured to sealably couple to any one of the flow control modules. In the same or other examples, each of the substrate receiver modules is configured to perform at least one function selected from the group consisting of (a) applying heat to the semiconductor substrate, (b) flowing gas to a backside of the semiconductor substrate, and (c) and applying RF bias to the semiconductor substrate.

These and other examples are described further below with reference to the figures.

### BRIEF DESCRIPTION OF THE DRAWINGS

FIG. 1A is a schematic perspective view of an integrated benchtop semiconductor process cell illustrating various components of the cell, in accordance with some examples.

FIG. 1B is a schematic front view of the integrated benchtop semiconductor process cell in FIG. 1A, in accordance with some examples.

FIG. 1C is a schematic side view of the integrated benchtop semiconductor process cell in FIG. 1A, in accordance with some examples.

FIG. 1D is a schematic side view of another example of an integrated benchtop semiconductor process cell.

FIG. 2A is a schematic view of one example of a semiconductor process tool.

FIG. 2B is a block diagram of a semiconductor process tool, illustrating the modularity of the tool, in accordance with some examples.

FIG. 3 is a top schematic view of one example of a cell-based semiconductor fab formed by interconnecting multiple integrated benchtop semiconductor process cells.

FIG. 4 is a top schematic view of another example of a cell-based semiconductor fab formed by interconnecting multiple integrated benchtop semiconductor process cells.

FIG. 5A is a process flowchart corresponding to a method of fabricating a MEMS pressure sensor such that all operations of this method are performed by one or more integrated benchtop semiconductor process cells.

FIG. 5B is a process flowchart corresponding to a method of fabricating a MEMS transducer such that all operations of this method are performed by one or more integrated benchtop semiconductor process cells.

FIG. 5C is a process flowchart corresponding to a method of fabricating a microheater such that all operations of this method are performed by one or more integrated benchtop semiconductor process cells.

FIG. 5D is a process flowchart corresponding to a method of fabricating a cantilever such that all operations of this method are performed by one or more integrated benchtop semiconductor process cells.

FIG. 6 is a process flowchart corresponding to a general method of comprising multiple semiconductor processing operations performed by one or more integrated benchtop semiconductor process cells.

FIG. 7A is a schematic plot illustrating the cost, time, and complexity associated with a vacuum as a function of the evacuated volume.

FIG. 7B is a schematic plot illustrating the cost, time, and complexity associated with RF generation as a function of the processed volume.

FIG. 7C is a schematic plot illustrating the cost, time, and complexity associated with achieving uniform plasma density as a function of the substrate size.

FIG. 7D is a schematic plot illustrating the temperature uniformity as a function of the substrate size.

FIG. 8 is a block diagram representing various components used for building a semiconductor fabrication line, comprising semiconductor process tools, and using a semiconductor tool library, in accordance with some examples.

FIG. 9 is a process flowchart corresponding to a method for building a semiconductor fabrication line, comprising semiconductor process tools, and using a semiconductor tool library, in accordance with some examples.

FIG. 10A is a block diagram representing various inputs used for designing and building a semiconductor fabrication line, in accordance with some examples.

FIG. 10B is a block diagram representing various components of a semiconductor fabrication line, in accordance with some examples.

FIG. 11 is a block diagram representing various components of a semiconductor process tool, in accordance with some examples.

### DETAILED DESCRIPTION

In the following description, numerous specific details are outlined in order to provide a thorough understanding of the presented concepts. The presented concepts may be practiced without some or all of these specific details. In other instances, well-known process operations have not been described in detail to not unnecessarily obscure the described concepts. While some concepts will be described in conjunction with the specific examples, it will be understood that these examples are not intended to be limiting.

### INTRODUCTION

Conventional semiconductor processing typically focuses on integrated circuits used in computers and other applications. Integrated circuits tend to be very complex and require complex and expensive manufacturing using relatively standardized semiconductor processes. For example, the same process or, more generally, the same set of processes can be used for processing thousands of different types of integrated circuits. These trends have resulted in high-volume semiconductor foundries (or fabs) that often cost billions of dollars to set up and require high utilization to justify these high costs. For example, a semiconductor foundry is typically set up to process tens of thousands of 300-mm wafers each month with each wafer including hundreds, if not thousands, of integrated circuits. Besides the large capital expenditures, high-volume semiconductor foundries can take months to build and are generally not easily adaptable to new designs of semiconductor devices.

At the same time, the application of semiconductor devices is rapidly growing beyond integrated circuits and currently includes quantum computing, augmented reality/virtual reality, aerospace applications, and sensors (e.g., microelectromechanical systems (MEMS) sensors), neuromorphic devices, and biosensors among many other examples. A large number of new applications is typically associated with a smaller number of devices needed for each application. In other words, the production scales are often in thousands of devices, if not hundreds, or even individual devices. As such, high-volume semiconductor foundries are not suitable for such devices

Described herein are integrated benchtop semiconductor process cells and cell-based semiconductor fabs. A process cell includes a tool compartment in which one or more semiconductor process tools are positioned. Process tools are configured for processing substrates that are less than 60 millimeters in diameter (e.g., 2 inches or about 50 millimeters) thereby reducing the cost and size of the cell (in comparison to conventional tools). Furthermore, process tools are highly configurable, which allows for the design and assembly of process cells and fabs relatively fast and with minimal costs. For example, a semiconductor tool library, comprising multiple different types of modules, can be used to assemble individual process tools and, from these tools, semiconductor fabrication cells, lines, and fabs. The terms “cells”, “lines”, and “fabs” are used interchangeably to represent a collection of multiple semiconductor tools arranged together according to a process sequence to fabricate a semiconductor device.

A process cell includes one or more tool compartments in which one or more semiconductor process tools are positioned. The cell also comprises one or more support modules fluidically coupled to the semiconductor process tools and external connections (e.g., exhaust, electrical, and/or compressed gas), which collectively support all operations of the semiconductor process tools. For example, multiple semiconductor process tools of the same process cell share these support modules thereby reducing the number of support modules needed for the overall operation. As such, a cell can be operable as a standalone unit with minimal external connections, it can be integrated with one or more additional cells to form a cell-based semiconductor fab. A cell can have a minimal footprint (e.g., less than 2-3 square meters) while supporting one or more tools (e.g., two, three, four, or more different tools). As such, an entire semiconductor fab can be formed with minimal facility requirements (e.g., space, power) to produce low-volume semiconductor devices.

Reducing the size and facility requirements of integrated benchtop semiconductor process cells makes the production of low-volume semiconductor devices feasible. One example of such semiconductor devices includes MEMS sensors, which have a particularly diverse range of configurations. Unlike conventional integrated circuits (which are heavily dependent on specific circuit layouts and corresponding lithographic masks), MEMS technology is process and material-focused using different substrates, processes, and materials. As such, MEMS are much harder, if possible, to process using conventional semiconductor fabs.

Overall, smaller substrate sizes reduce the complexity and costs of semiconductor processing and allow using versatile and configurable tools that can be used for fabricating MEMS sensors and other like devices. Furthermore, semiconductor process tools and integrated benchtop semiconductor process cells formed using these tools (as well as larger fabs formed using multiple process cells) are highly modular and adaptable. New processes are easily accommodated by adding new tools, which can be specifically assembled using a tool library. These new tools can be added to existing process cells or used to form new process cells. This modular approach allows setting up very specific fabrication lines that have not been possible with conventional large-scale fabs. For example, each process line/fab (comprising one or more process cells with multiple process tools) can be used to fabricate a specific type of device, e.g., 1 line: 1 device approach). The line can be then retooled for the fabrication of a different device in a matter of days or even hours. Finally, high levels of scalability can be achieved by running multiple lines in parallel using the same small-scale facility (e.g., physical space, power supplies, and the like). While setting up a new production line, the “time-to-first-wafer” can be less than a month with minimal costs and high production flexibility for future changeovers. At the same time, the processing costs can be comparable to that of large-scale fabs due to much smaller initial capital expenditures.

### Examples of Integrated Benchtop Semiconductor Process Cells

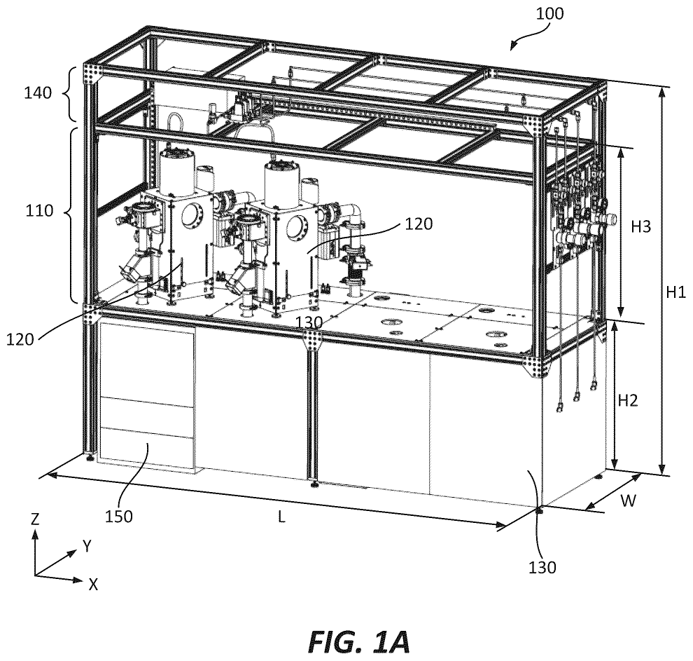

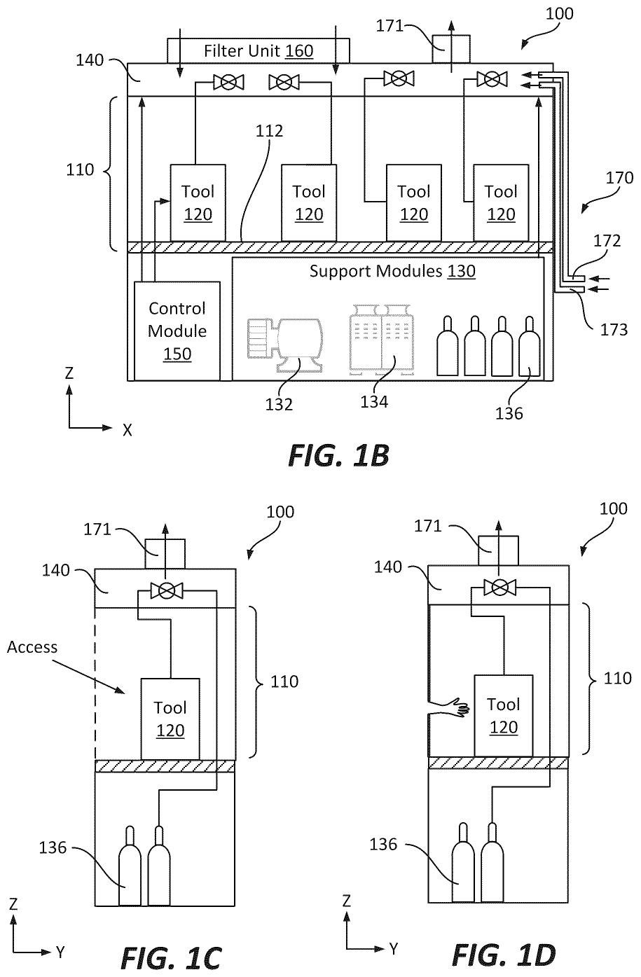

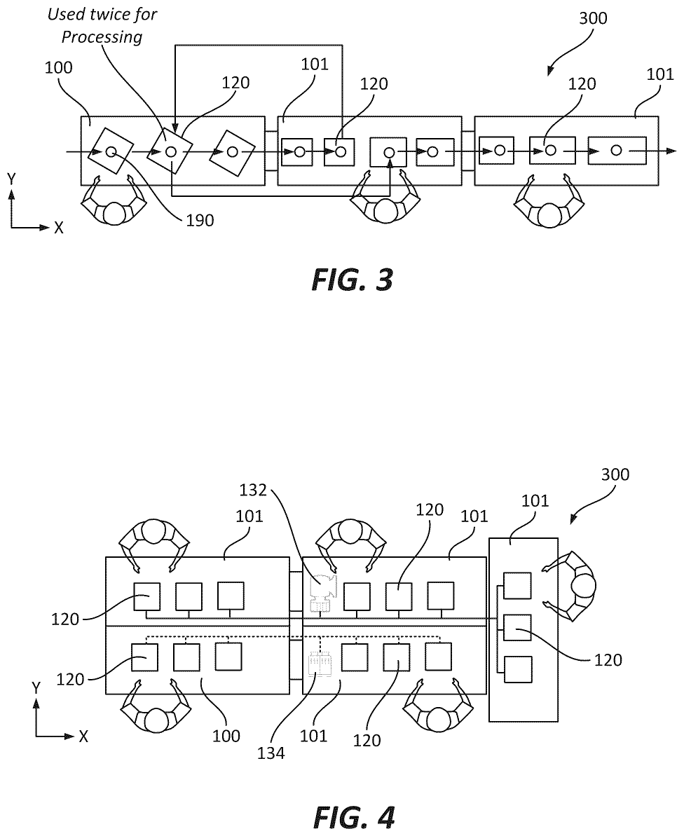

FIG. 1A is a perspective view of integrated benchtop semiconductor process cell 100 for processing a semiconductor substrate 190, in accordance with some examples. FIGS. 1B-D are corresponding front and side schematic views. Integrated benchtop semiconductor process cell 100 can be used as a standalone unit. Various examples presented in this section are directed to this standalone operation such that all key operational components unit are provided within the unit. Alternatively, multiple integrated benchtop semiconductor process cells 100 can be assembled into cell-based semiconductor fab 300 as further described below with reference to FIGS. 3 and 4. In these examples, various components (e.g., gas supplies, vacuum pumps, water chillers, and the like) of integrated benchtop semiconductor process cells 100 can be shared among these multiple cells.

Referring to FIG. 1A, integrated benchtop semiconductor process cell 100 comprises one or more tool compartments 110, one or more semiconductor process tools 120, one or more support modules 130, and external connections 170. A combination of support modules 130 and external connections 170 provides all facilities for operating each semiconductor process tool 120 (e.g., when integrated benchtop semiconductor process cell 100 is used as a standalone unit). The number of external connections 170 is minimal and could be three, two, or even less. It should be noted that these external connections 170 are provided by external facilities. As such, integrated benchtop semiconductor process cell 100 requires very minimal external facilities for its operation thereby allowing using integrated benchtop semiconductor process cell 100 in many different production environments.

Furthermore, the size of integrated benchtop semiconductor process cell 100 is minimal. In some examples, integrated benchtop semiconductor process cell 100 has a footprint of less than 3 square mone meters, or even less than 2 square meters. Referring to FIG. 1A, the length (L) of integrated benchtop semiconductor process cell 100 can be less than 4 meters, less than 3.5 meters, or even less than 3 meters. In the same or other examples, the width (W) of integrated benchtop semiconductor process cell 100 can be less than 2 meters, less than 1.5 meters, or even less than 1 meter. It should be noted that even with such small dimensions, integrated benchtop semiconductor process cell 100 can accommodate one or more semiconductor process tools 120 as well as various support modules 130 needed for the operations of these tools. In some examples, the height (H1) of integrated benchtop semiconductor process cell 100 can be less than 3 meters, less than 2.5 meters, or even less than 2 meters. Overall, the size of integrated benchtop semiconductor process cell 100 is such that the cell can be easily positioned in various types of facilities without a need for large floor space and/or tall ceilings. In fact, the size of integrated benchtop semiconductor process cell 100 is comparable to a typical glovebox or a fumehood used in laboratories/production floors.

Referring to FIG. 1A, in some examples, integrated benchtop semiconductor process cell 100 also comprises one or more controllers 140, control modules 150, and/or filter unit 160. For example, controllers 140 can be positioned above tool compartment 110 and control the flow of gases, power, and other facilities to semiconductor process tools 120. Filter unit 160 can be also positioned above tool compartment 110 or even above controllers 140 and used for delivering filtered air into tool compartment 110. Control modules 150 can be communicatively coupled to various sensors and actuators of controllers 140, semiconductor process tools 120, and other components and used for controlling the operation of semiconductor process tools 120 or, more generally, for controlling the operation of integrated benchtop semiconductor process cell 100 as a whole. Control modules 150 can be positioned under tool compartment 110, e.g., next to support modules.

Each component of integrated benchtop semiconductor process cell 100 will now be described in more detail with reference to FIGS. 1A-1D. Tool compartment 110 can comprise benchtop 112 for positioning one or more semiconductor process tools 120 thereon. In some examples, benchtop 112 is positioned at a set height (H2) from the bottom of integrated benchtop semiconductor process cell 100 either for a standing operator position (e.g., H2=1-1.2 meters) or for a sitting operator position (e.g., H2=0.6-0.8 meters). It should be noted that an operator needs to access one or more semiconductor process tools 120, e.g., to transfer semiconductor substrate 190, which can also be transported using specialized wafer carriers.

Referring to FIG. 1C, in some examples, tool compartment 110 can be open to the environment, e.g., have a front access opening. For example, integrated benchtop semiconductor process cell 100 can be operated in a clean room. Furthermore, filter unit 160 can provide a sufficient flow of clean air to minimize substrate contamination. For example, the specific position and configuration of filter unit 160 allow achieving a cleanroom-like environment (e.g., up to Class 10 or ISO 4 cleanroom environment) without actually using a cleanroom.

Referring to FIG. 1D, in some examples, tool compartment 110 is an enclosed area (e.g., isolated from the environment) or an open area. For example, tool compartment 110 has a transparent front panel or wall with gloves for operators to reach and manipulate one or more semiconductor process tools 120 inside tool compartment 110. In these examples, the cleanliness of tool compartment 110 can be maintained at a much higher level, such as Class 10 (ISO 4) or better. This enclosed tool compartment 110 can also be used to achieve specific environmental conditions (e.g., low humidity, low oxygen content, and the like) and the process semiconductor substrate 190 that are sensitive to ambient air.

In some examples, the height (H3) of tool compartment 110 is between 1 meter and 2.5 meters to provide sufficient access to one or more semiconductor process tools 120. The side of benchtop 112 can be the same as the footprint of integrated benchtop semiconductor process cell 100 described above. Benchtop 112 is modular and can be integrated together with additional benchtops to form a fab as further described below with reference to FIGS. 3 and 4.

Referring to FIGS. 1A-1D, integrated benchtop semiconductor process cell 100 comprises one or more semiconductor process tools 120, positioned in tool compartment 110 on benchtop 112. While FIG. 1A illustrates two semiconductor process tools 120 and FIG. 1B illustrates four semiconductor process tools 120, any number of tools are within the scope. This number depends on the size of benchtop 112 (described above), the size of each semiconductor process tools 120 (described below), access requirements for each tool, the process sequence, and other factors.

Semiconductor process tools 120 are used for processing semiconductor substrate 190 in various manners. Once semiconductor substrate 190 is processed in one tool, semiconductor substrate 190 can be transferred into another tool (e.g., by an operator). In some examples, the substrate transfer can be achieved manually (e.g., by an operator) or automatically (e.g., using specially configured and controlled robotic arms).

The type of semiconductor process tools 120 depends on the type of processes that need to be performed, some of which are further described below. In some examples, semiconductor substrate 190 is positioned on or in substrate carriers, which are moved from one tool to another tool, thereby eliminating the need for additional direct contact with semiconductor substrate 190.

Semiconductor process tools 120 are selected from the group consisting of a lithography tool, a polymer processing tool (e.g., a photoresist process tool), a thermal process tool, a chemical vapor deposition (CVD) tool, a sputtering tool, an atomic layer deposition (ALD) tool, an ion-etching tool, a wafer cutting tool, and reactive ion etch, deep reactive ion etch, vapor etch, wet etch, electroplating, wafer bonding, and the like.

In some examples, semiconductor substrate 190 has a diameter at or less than 100 millimeters, less than 80 millimeters, or even less than 60 millimeters. As noted above, such substrate sizes allow reducing the size of process tools, which in turn helps to reduce the cost and increase the modularity.

Referring to FIGS. 1A and 1B, integrated benchtop semiconductor process cell 100 also comprises one or more support modules 130, fluidically coupled to each of one or more conduits. In some examples, this fluidically coupling is controlled by controllers 140. It should be noted that controllers 140 are positioned closer to semiconductor process tools 120 than one or more support modules 130. As such, the volume inside conduits, which fluidically couples semiconductor process tools 120 and controllers 140 is minimized. This approach allows positioning support modules 130 further away from semiconductor process tools 120, e.g., under tool compartment 110 or, more specifically, under benchtop 112.

Some examples of support modules 130 include vacuum pump 132, water chiller 134, and gas storage 136, and gas distribution and control equipment. In some examples, support modules 130 of the same cell comprise all three of more vacuum pump 132, water chiller 134, and gas storage 136. Alternatively, when integrated benchtop semiconductor process cell 100 is integrated with other cells, one or more of these three support modules can be shared and do not need to be included in each process cell.

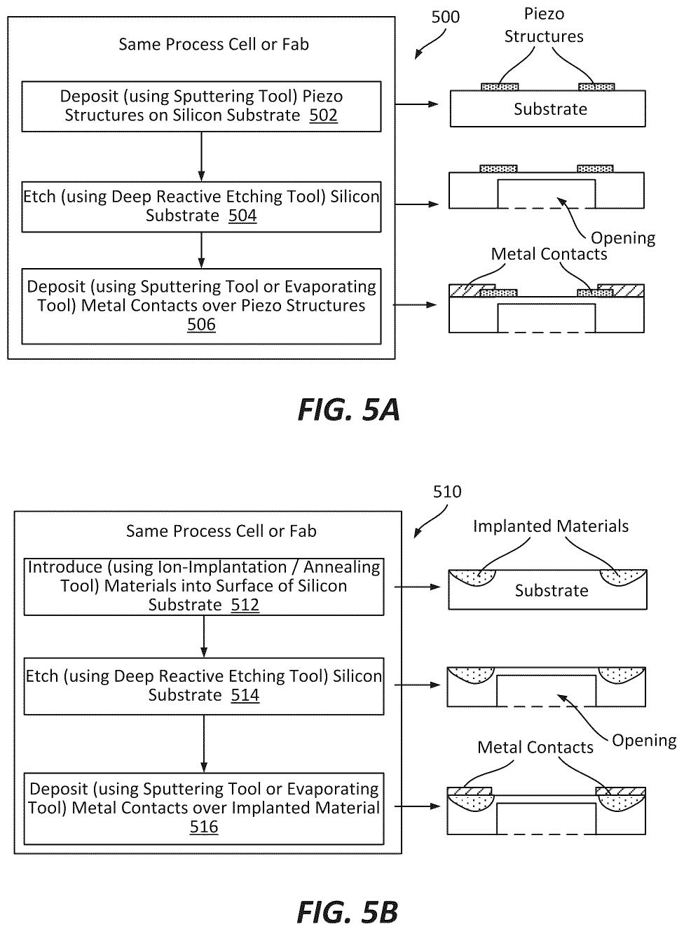

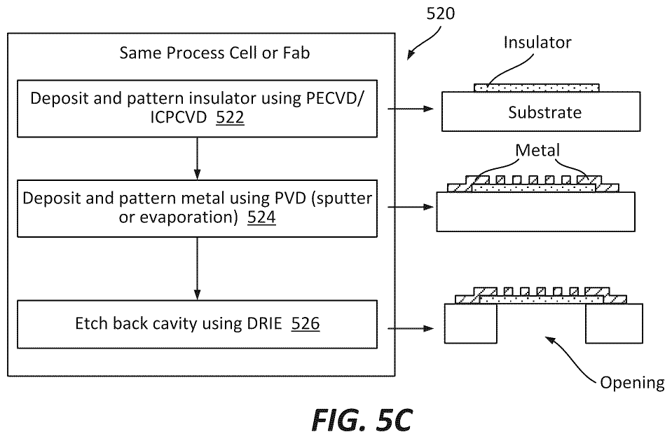

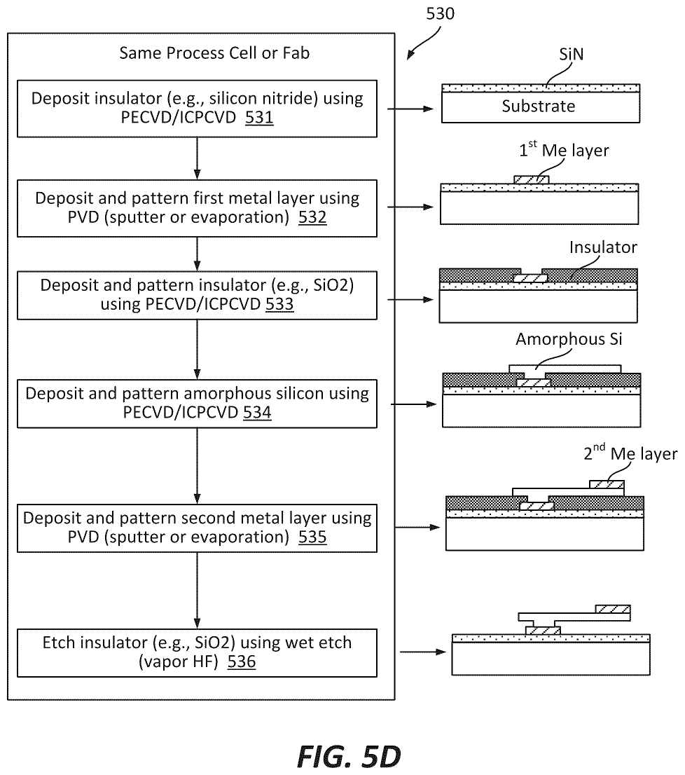

Because of the small size of all conduits and semiconductor process tools 120, vacuum pump 132 can be the same size as a mechanical vacuum pump used in a single conventional chamber. This is because the overall evacuation volume of semiconductor process tools 120 is significantly smaller than conventional semiconductor equipment. For comparison, conventional semiconductor process tools typically require turbo vacuum pumps, which are a lot more expensive. Additional aspects of the vacuum pump selection and complexity is described below with reference to FIG. 5A.

In some examples, gas storage 136 comprises all gases needed for the complete operation of all semiconductor process tools 120. Some examples of gases include, but are not limited to, SF₆, C₄F₈, CF₄, O₂, Ar, N₂, XeF₂, He, CHF₃, C₃F₈, C₂F₆, CH₄, SiH₄, Si₂H₆, Cl₂, BCl₃, and the like. For example, gas storage 136 comprises at least 2 gas storage containers, at least 4 gas storage containers, at least 6 gas storage containers, or even at least 8 gas storage containers.

Referring to FIG. 1B, integrated benchtop semiconductor process cell 100 also comprises external connections 170, such as exhaust connection 171, electrical power connection 172, and compressed-gas connection 173. When integrated benchtop semiconductor process cell 100 is operable as a standalone unit, a combination of external connections 170 and one or more support modules 130 is configured to support all operations of each and all semiconductor process tools 120 of integrated benchtop semiconductor process cell 100. Alternatively, when integrated benchtop semiconductor process cell 100 is integrated with other cells, a combination of external connections 170 and support modules 130 of these multiple cells is configured to support all operations of each and all semiconductor process tools 120 in all cells.

The number of these external connections 170 can be three or less. For example, external connections 170 can include exhaust connection 171 and electrical power connection 172 but not compressed-gas connection 173. Instead, compressed gas can be provided by one of support modules 130, e.g., a compressor or, more specifically, an air compressor. In this example, a combination of exhaust connection 171, electrical power connection 172, and one or more support modules 130 is configured to support all operations of each and all semiconductor process tools 120 of integrated benchtop semiconductor process cell 100.

In some examples, integrated benchtop semiconductor process cell 100 has a maximum power consumption of less than 100 kW, less than 60 kW, less than 30 kW, or even less than 10 kW. In other words, electrical power connection 172 can be a standard industrial power connection.

In some examples, integrated benchtop semiconductor process cell 100 further comprises one or more controllers 140, positioned proximate to one or more semiconductor process tools 120. One controller example is a mass flow controller fluidically coupling one or more semiconductor process tools 120 to gas storage 136. Additional controller examples include, but are not limited to, one or more RF impedance matcher for one or more of a DC power supply, an RF power supply, a phase shifter, an impedance matching network, a pressure controller, a flow controller, and a heater supply.

In some examples, integrated benchtop semiconductor process cell 100 further comprises control modules 150, communicatively coupled to one or more controllers 140. Control modules 150 comprise a set of instructions for operating plurality of controllers 140. Control modules 150 can include a computer system and/or power supplies, e.g., RF power supplies for individual tools. A computer system can comprise a processor unit, memory, persistent storage, communications unit, and input/output unit. For example, the processor unit serves to execute instructions for software that may be loaded into the memory. The memory and persistent storage can be in the form of computer-readable storage devices (e.g., random access memory, a hard drive, a flash memory). The communications unit can provide communication with other computer systems or devices (e.g., over local and/or global networks). The input/output unit may include a keyboard, mouse, and/or display. Overall, instructions for the operating system, applications, and/or programs may be located in the storage devices, which are in communication with the processor unit. Various processes may be performed by the processor unit using computer-implemented instructions. These instructions are referred to as program code, computer usable program code, or computer-readable program code.

In some examples, integrated benchtop semiconductor process cell 100 further comprises filter unit 160 configured to flow filtered air (e.g., laminar flow) into tool compartment 110 thereby reducing the contamination level in tool compartment 110 around one or more semiconductor process tools 120. For example, filter unit 160 can be positioned above tool compartment 110 and is configured to direct filtered air toward benchtop 112 as, e.g., schematically shown in FIG. 1B. In some examples, integrated benchtop semiconductor process cell 100 comprises multiple filter units 160.

FIG. 1B illustrates some physical and communicative couplings between different components of integrated benchtop semiconductor process cell 100. For example, control modules 150 can be communicatively coupled to one or more controllers 140 and/or semiconductor process tools 120 to control the operation of these semiconductor process tools 120. In some examples, semiconductor process tools 120 can be equipped with various sensors (e.g., pressure sensors, temperature sensors, position sensors) that provide feedback to control modules 150. Support modules 130 are fluidically coupled to controllers 140. Similarly, external connections 170 can be fluidically (e.g., compressed-gas connection 173) and/or electrically (e.g., electrical power connection 172) coupled to controllers 140. Controllers 140 are, in turn, fluidically and/or electrically coupled to semiconductor process tools 120.

### Examples of Semiconductor Process Tools

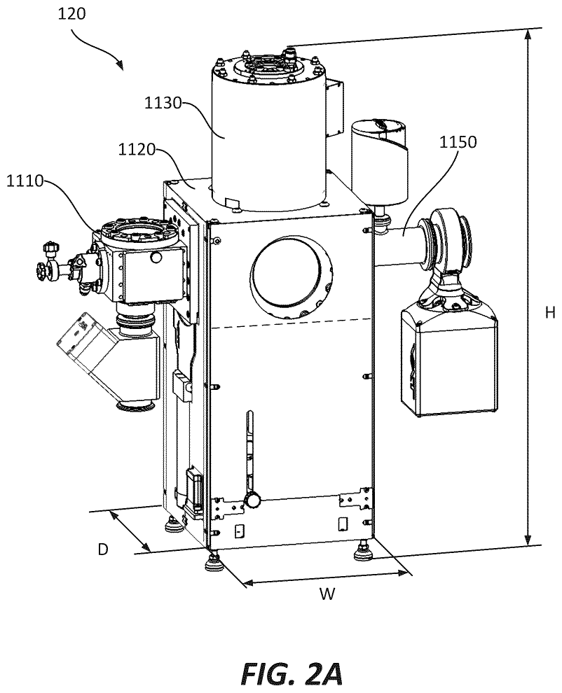

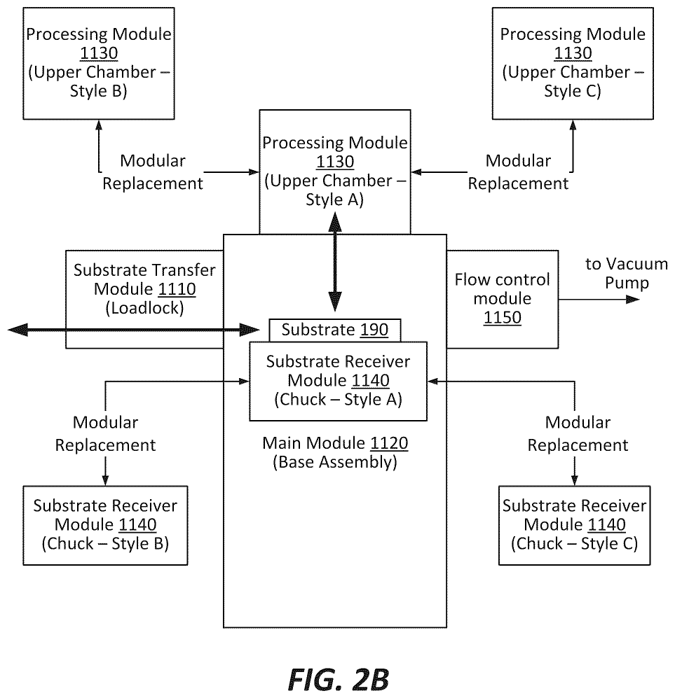

FIG. 2A illustrates semiconductor process tool 120, in accordance with some examples. The size of semiconductor process tool 120 is such that semiconductor process tool 120 can be used on benchtop 112 of integrated benchtop semiconductor process cell 100. For example, semiconductor process tools 120 generally have a footprint (i.e., the width (W) and/or the depth (D))) of less than 0.5 meters by 0.5 meters and have a height of up to 1.5 meters. For comparison, a conventional semiconductor tool typically has a size of 5-100 m². Furthermore, the weight of semiconductor process tool 120 can generally be between 20 kg and 60 kg, which makes it possible for an operator to move and rearrange on benchtop 112.

Referring to FIGS. 2A and 2B, semiconductor process tool 120 is an assembly of various components, such as a main module 1120, a processing module 1130, a substrate transfer module 1110, a substrate receiver module 1140, and a flow control module 1150. Main module 1120, which may be also referred to as a base assembly, is used to connect, support, and or house other modules. For example, main module 1120 may be in the form of a cube with other modules attached (e.g., sealably and fluidically coupled) to different sides of this cube. In other words, main module 1120 can form sealed temporary connections with each other module attached to main module 1120.

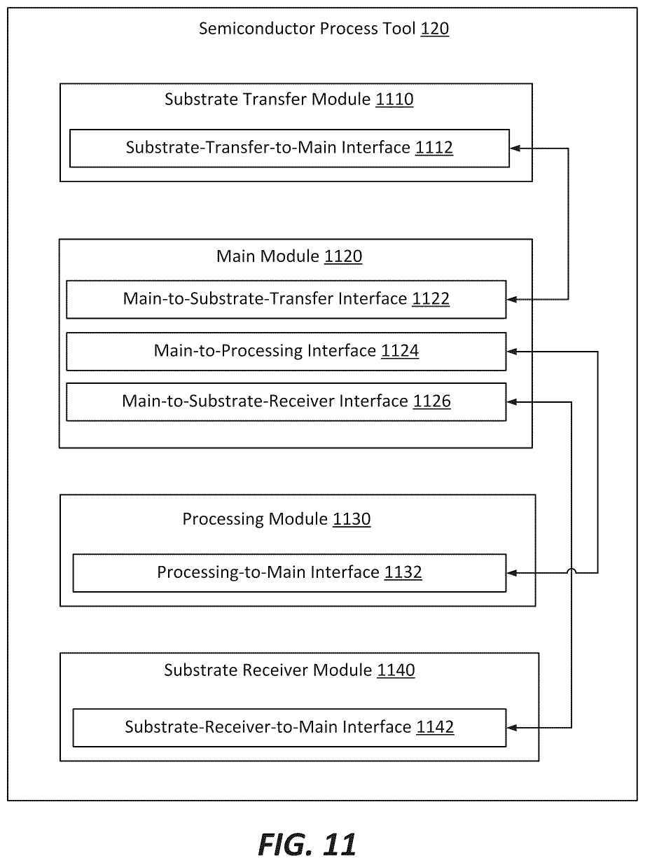

Processing module 1130, which may be also referred to as an upper chamber, may be attached to the first/top surface of main module 1120. Different types of processing module 1130 (e.g., style A, style B, style C, etc.) may be interchangeably connected to main module 1120. The type of processing module 1130 (and, in some examples, the type of substrate receiver module 1140) defines semiconductor operations that can be performed on semiconductor substrate 190. It should be noted that each type of module, connected to main module 1120, can be replaced independently from any other module. For example, processing module 1130 can be replaced, while substrate receiver module 1140 can be retained. Some examples of processing module 1130 include, but are not limited to, a sputtering tool, an evaporating tool, a deep reactive ion etching (DRIE), a reactive ion etching tool, a plasma etching tool, a plasma cleaning tool, an ion-implantation tool, an annealing tool, a plasma-enhanced chemical vapor deposition (PECVD) tool, an inductively coupled plasma chemical vapor deposition (ICPCVD) tool, an atomic layer deposition (ALD) tool, a vapor etching tool, and a wet chemical processing tool. Additional features and connections of processing module 1130 to main module 1120 are described below with reference to FIG. 11.

Substrate transfer module 1110 may be also referred to as a load lock. Substrate transfer module 1110 is used to transfer semiconductor substrate 190 from the environment to main module 1120 and, in some examples, may protrude into main module 1120. Once inside main module 1120, semiconductor substrate 190 can be supported by substrate receiver module 1140, which may be also referred to as a chuck. Different types of substrate receiver module 1140 are within the scope (e.g., modules equipped with heaters, gas flow lines, RF biasing mechanisms, and measurement systems). Finally, control module 1150 can be used to control the pressure inside module 1120. As such, substrate receiver module 1140 can be configured to perform at least one function selected from the group consisting of (a) applying heat to the semiconductor substrate, (b) flowing gas to a backside of the semiconductor substrate, and (c) and applying RF bias to the semiconductor substrate.

### Examples of Cell-Based Semiconductor Fabs

Integrated benchtop semiconductor process cell 100 described above may be used together with one or more additional integrated benchtop semiconductor process cells, provided in the same location and used to process the same set of semiconductor substrates. A set of multiple integrated benchtop semiconductor process cells can be specifically configured to process semiconductor substrates according to a specific processing sequence and may be referred to as a cell-based semiconductor fab. Various examples of a cell-based semiconductor fab are described below with reference to FIGS. 3 and 4. Specifically, each cell may not have sufficient space to accommodate all semiconductor process tools 120 needed for this processing sequence. In some examples, a processing sequence may require 10 or more different processing operations, each requiring a different semiconductor process tool. It should be noted that while each integrated benchtop semiconductor process cell 100 can be reconfigured to use new semiconductor process tools, this reconfiguration process requires time. Furthermore, multiple integrated benchtop semiconductor process cells 100 can be used in the same cell-based semiconductor fab to perform the same semiconductor processing operations in parallel thereby increasing the throughput of the cell-based semiconductor fab.

Referring to FIGS. 3 and 4, cell-based semiconductor fab 300 comprises integrated benchtop semiconductor process cell 100 and one or more additional integrated benchtop semiconductor process cells 101. Any number of additional integrated benchtop semiconductor process cells 101 are within the scope, e.g., one, two (shown in FIG. 1A), three, four (shown in FIG. 1B), five, or more. The total number of cells and the configuration of each cell depends on the processing requirement for cell-based semiconductor fab 300.

Each of additional integrated benchtop semiconductor process cells 101 can be configured similarly to integrated benchtop semiconductor process cell 100 described above with reference to FIGS. 1A-1D. For example, additional integrated benchtop semiconductor process cell 101 can comprise tool compartment 110 with benchtop 112. Additional integrated benchtop semiconductor process cell 101 also comprises one or more semiconductor process tools 120, positioned in tool compartment 110 on benchtop 112. Various examples of these semiconductor process tools 120 are described above.

Semiconductor process tools 120 of all cells in cell-based semiconductor fab 300 can be arranged in various ways as will now be described with reference to FIG. 4. For example, semiconductor process tools 120 can be arranged in accordance with the operating sequence, e.g., at least two semiconductor process tools 120 used to perform two sequential operations are positioned next to each other in the same cell or two adjacent cells. This approach minimizes the substrate handling, i.e., the distance which semiconductor substrate 190 has to travel during its entire processing in cell-based semiconductor fab 300. In some examples, the same semiconductor process tool 120 is used for performing multiple operations as, e.g., is schematically shown in FIG. 3.

In some examples, integrated benchtop semiconductor process cell 100 and one or more additional integrated benchtop semiconductor process cells 101 are arranged in line as, e.g., is schematically shown in FIG. 3. This line may represent a sequence of operations. However, other arrangements (e.g., as shown in FIG. 4) are also within the scope. Two adjacent cells may be environmentally insulated from each other, e.g., using a load lock when the cells have environmentally-isolated tool compartments. Alternatively, two or more cells may form a joined environmentally-isolated tool compartment with no isolations between adjacent tool compartments.

Similar to integrated benchtop semiconductor process cell 100, additional integrated benchtop semiconductor process cell 101 also comprises one or more support modules 130, fluidically coupled to each of one or more semiconductor process tools 120. These support modules 130 can be also positioned under benchtop 112. In some examples, one or more support modules 130 in cell-based semiconductor fab 300 can be shared by semiconductor process tools 120 of different cells. This sharing can be similar to sharing support modules 130 within the cell (i.e., by semiconductor process tools 120 in the same cell). In the cell-to-cell sharing, one support module 130 of integrated benchtop semiconductor process cell 100 can be fluidically coupled to semiconductor process tool 120 of additional integrated benchtop semiconductor process cell 101. It should be noted that this support module 130 can be also coupled to one or more semiconductor process tools 120 of various other cells in cell-based semiconductor fab 300. In general, any support module 130 of any cell can be coupled to any semiconductor process tool 120 in cell-based semiconductor fab 300 including various one-to-one connections (e.g., one support module is coupled to one tool), one-to-many connections, many-to-one connections, and even many-to-many connections (e.g., multiple vacuum pumps are fluidically coupled to the same vacuum manifold supporting different semiconductor process tools 120). Overall this across-cell support within cell-based semiconductor fab 300 reduces the number of support modules 130 in the entire fab and enables additional capabilities and functionalities.

Some specific examples of sharing support modules 130 across different integrated benchtop semiconductor process cells 101 will now be described with reference to FIG. 4. Specifically, FIG. 4 illustrates vacuum pump 132 shared by or, more specifically, fluidically coupled to nine semiconductor process tools 120 positioned in three different cells. FIG. 4 also illustrates water chiller 134 shared by six semiconductor process tools 120 positioned in two different cells.

FIGS. 5A-5D illustrate various examples of processing a semiconductor substrate using integrated benchtop semiconductor process cell 100. Specifically, all steps of each process can be performed in one integrated benchtop semiconductor process cell 100 or several integrated benchtop semiconductor process cells 100 arranged into a fabrication line (i.e., a fab). Each step is performed by one of semiconductor process tools 120 in integrated benchtop semiconductor process cell 100. The selection of semiconductor process tools 120 depends on the processing operations needed.

For example, FIG. 5A corresponds to method 500 of fabricating a MEMS piezoelectric or piezoresistive transducer. Method 500 may commence with (block 502) depositing piezo structures (e.g., PZT, AlN (aluminum nitride)) on a silicon substrate. This operation may be performed using a sputtering tool and later patterned using a litographic tool. Method 500 may proceed with (block 504) etching the silicon substrate and forming an opening on the backside of the substrate (opposite the piezo structures). This operation may be performed using a deep reactive ion etching (DRIE) tool. By using a DRIE tool, the openings can be geometrically complex and have large aspect ratios, which can improve the performance and functionality of the devices. Method 500 may proceed with (block 506) depositing metal contacts (e.g., Au, Al, or Cr) over the piezo structures. This operation may be performed using a sputtering tool or an evaporating tool.

FIG. 5B illustrates an example of method 510 for fabricating a MEMS pressure sensor. Method 500 may commence with (block 512) introducing/implanting materials (e.g., boron, phosporous, or arsenic) into the surface of a silicon substrate. This operation may be performed using an ion-implantation/annealing tool. Method 500 may proceed with (block 514) etching the silicon substrate and forming an opening on the backside of the substrate (opposite to the implantation surface of the substrate). This operation may be performed using a deep reactive etching or wet etching tool. Method 500 may proceed with (block 516) with depositing metal contacts (e.g., Au, Al, or Cr) over the implanted material.

FIG. 5C illustrates an example of method 520 for fabricating a micro-heater, which can be used in applications such as gas-sensing. Method 500 may commence with (block 522) depositing and patterning an insulator (e.g., silicon nitride or silicon dioxide) over a silicon substrate. This operation may be performed using a plasma-enhanced chemical vapor deposition (PECVD) tool or a inductively coupled plasma chemical vapor deposition (ICPCVD) tool. Method 500 may proceed with (block 524) depositing and patterning a metal layer (e.g., Au, Al, or Cr). This operation may be performed using a sputtering tool or an evaporating tool. Method 500 may proceed with (block 526) etching back a cavity on the backside of the substrate (opposite of the metal layer). This operation may be performed using a deep reactive etching or wet etching tool.

FIG. 5D illustrates an example of method 530 for fabricating a cantilever, for use in applications such as electromechanical switches or fluid valves. Method 500 may commence with (block 531) depositing an insulating layer (e.g. silicon nitride) on the surface of a silicon substrate. This operation may be performed using a PECVD/ICPCVD tool. Method 500 may proceed with (block 532) deposit and pattern a first metal layer (e.g., Au, Al, or Cr) using a PVD tool (e.g., a sputter tool or an evaporation tool). Method 500 may proceed with (block 533) depositing and patterning an insulator layer (e.g., silicon dioxide) using a PECVD/ICPCVD tool. Method 500 may proceed with (block 534) depositing and patterning an amorphous silicon layer using a PECVD/ICPCVD tool. Method 500 may proceed with (block 535) depositing and patterning a second metal layer using a PVD tool (a sputtering tool or an evaporation tool). Method 500 may proceed with (block 536) etching the first insulator (e.g., silicon dioxide) using a vapor- or wet-etch tool (e.g., using vapor high-frequency plasma). Using tools in a sequence like this allows complex and delicate structures to be fabricated such that they are protected from outside contaminants and forces until the final steps where they are released and allowed to function. This can dramatically increase manufacturing yield.

While FIGS. 5A-5D illustrate only four processing examples, the modularity and size of semiconductor process tools 120 allow arranging all kinds of fabrication lines (either in a single integrated benchtop semiconductor process cell 100 or in a combination of integrated benchtop semiconductor process cells 100 arranged into the line). Some additional examples of MEMS and other devices that can be fabricated using integrated benchtop semiconductor process cells 100 include, but are not limited to, microfluidic devices, micromirrors, actuators, resonators, environmental sensors, inertial measurement devices, vibration isolators, and energy harvesters.

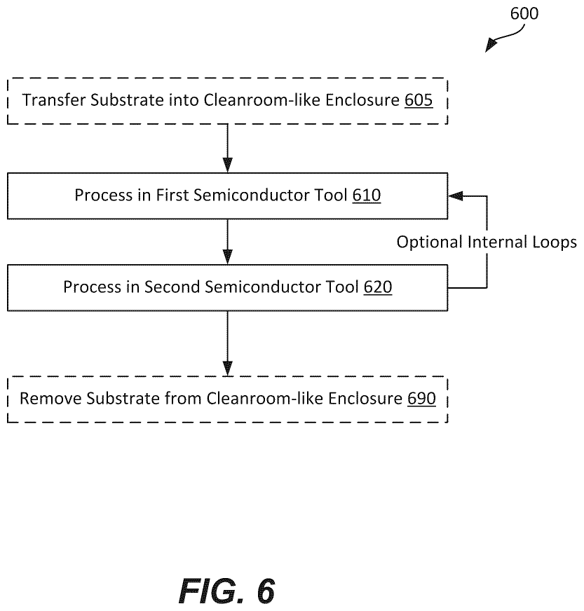

### Examples of Operating Integrated Benchtop Semiconductor Process Cells—FIG. 6

FIG. 6 is a process flowchart corresponding to method 600 for processing semiconductor substrate 190 using integrated benchtop semiconductor process cell 100, in accordance with some examples. In some examples, method 600 comprises (optional block 605) transferring a substrate into a cleanroom-like enclosure of an integrated benchtop semiconductor process cell, one example of which is shown in FIG. 1D. For example, the enclosure can be equipped with a load lock for transferring the substrate. Additionally, substrates can be moved between process cells (cleanroom-like enclosure) via clean boxes.

Method 600 proceeds with (block 610) processing the substrate using the first semiconductor process tool of the integrated benchtop semiconductor process cell. The tool type and the corresponding process can be selected based on the specific processing sequence for this substrate. A couple of examples are presented above with reference to FIGS. 5A, 5B, 5C, and 5D.

Method 600 proceeds with (block 620) processing the substrate using the second semiconductor process tool of the integrated benchtop semiconductor process cell. Again, the tool type and the corresponding process can be selected based on the specific processing sequence for this substrate. In some examples, both process tools (used for two sequential processing steps) are positioned in the same process cell thereby reducing the transfer distance and streamlining the overall process. In fact, both process tools (used for two sequential processing steps) can be positioned next to each other. Alternatively, the two process tools can be positioned in different process cells (e.g., two adjacent process tools).

Method 600 may continue with processing in additional process tools up until all processing steps are completed. In some examples, the same process tool is used one or more times in the same process sequence.

Method 600 may involve (block 690) removing the substrate from the cleanroom-like enclosure if one was used.

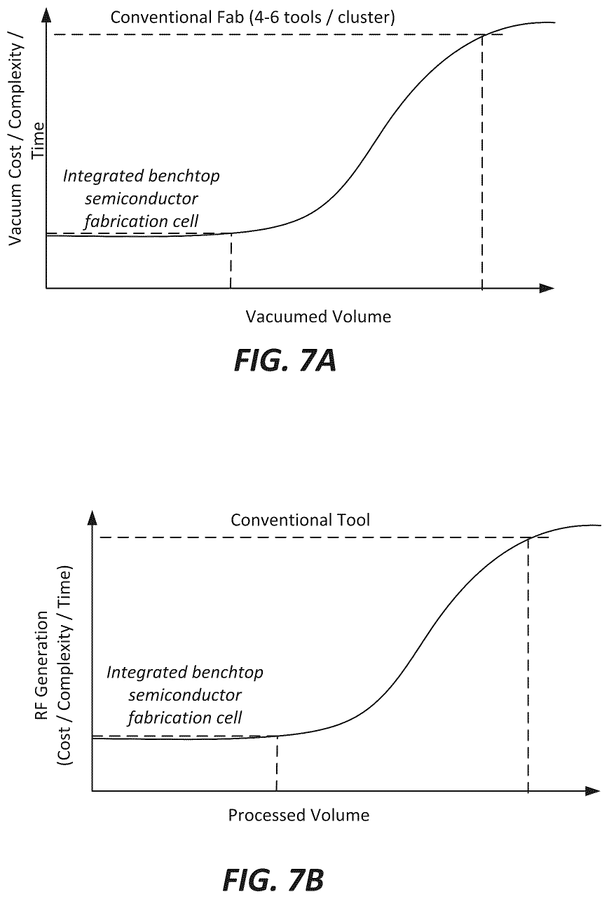

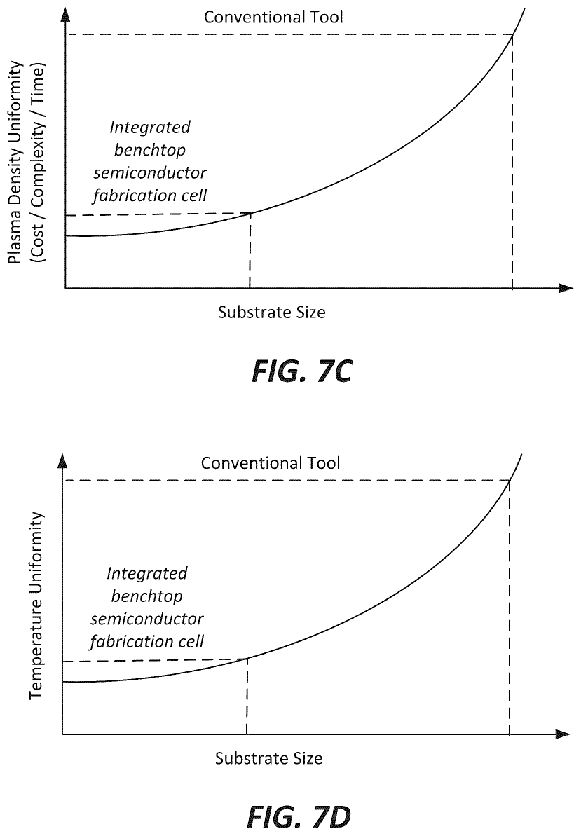

### Small Scale and Tool Integration Advantages—FIGS. 7A-7D

Due to the small scale of semiconductor process tools 120, integrated benchtop semiconductor process cells 100 and cell-based semiconductor fabs 300 can achieve various benefits that are not available with conventional semiconductor tools. This difference in size results in semiconductor process tools 120 being portable and integrated benchtop semiconductor process cells 100 being highly configurable. Specifically, the large size and cost of the components used in existing commercial semiconductor makes it both physically and logistically difficult to reconfigure individual tools or tools within a processing line. Smaller semiconductor process tools 120 can be easily replaced with another tool in a cell, e.g., easily rearranged, connected to support modules 130, and generally reconfigured as further described below with reference to tool libraries.

Another benefit of small tool size is the small internal volume of these tools. For example, semiconductor process tools 120 (described herein) have an internal volume of less than 5 L or even less than 1 L. For comparison, a conventional semiconductor tool typically has an internal volume of 10-100 L. This internal volume difference reduces the complexity and cost of operating these semiconductor process tools 120 (in comparison to conventional semiconductor tools) as will now be described with reference to FIGS. 7A-7D.

FIG. 7A is a schematic plot of the complexity of reaching a certain vacuum condition as a function of the evacuated volume. For purposes of this disclosure, the vacuum complexity is an aggregate factor that includes equipment type and costs, the time required to achieve this vacuum condition, and the like. For small volumes, the complexity is rather minimal due to the type of equipment needed (e.g., mechanical vacuum pumps). Larger volumes require more sophisticated equipment, such as turbo vacuum pumps.

FIG. 7B is a schematic plot of the complexity of generating a certain RF condition as a function of the processed volume or chamber size. For example, a larger volume requires more RF power to ignite and sustain plasma conditions. At the same time, high-power generators are more expensive as they require different architectures and more expensive components to build. Large plasma discharges may also required external confinement and modulation to attain suitable densities and uniformity.

FIG. 7C is a schematic plot of the complexity of maintaining plasma uniformity as a function of the evacuated volume. It should be noted that with larger chambers, complex designs are required to achieve and maintain the plasma uniformity. Large plasma discharges may also require external confinement and modulation to attain suitable densities and uniformity.

FIG. 7D is a schematic plot of the complexity of maintaining temperature/thermal uniformity as a function of the processed substrate size. When processing large substrates, different control methods and designs are required, e.g., multi-zone substrate heaters or multi-chamber averaging. These add to the complexity, size, and cost of processing tools.

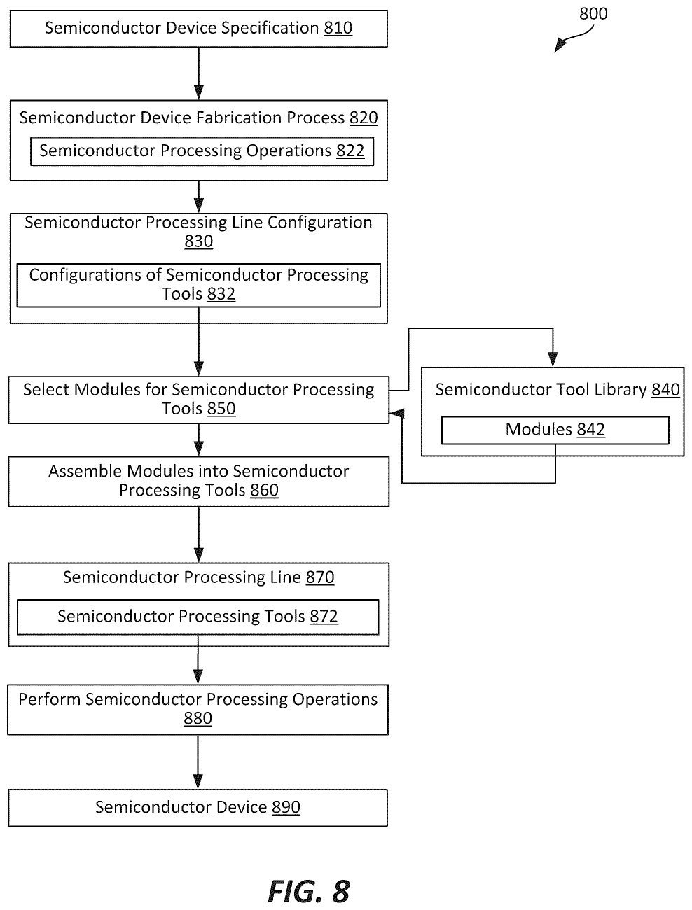

### Examples of Semiconductor Tool Libraries—FIG. 8

As noted above, the fabrication of semiconductor devices can involve many different operations, each requiring specially configured tools. The number of operations and tools depends on the complexity of the fabricated devices and can easily exceed tens of different tools. Obtaining and setting up each tool (in conventional semiconductor manufacturing environments) can be cost-prohibitive, especially for low-volume fabrication. Each tool can be very expensive and tends to be purposed for a specific operation. Reconfiguring an existing tool for a new process can be very expensive or even impossible.

Described herein are methods and systems for reducing the complexity when building semiconductor processing lines comprising different types of semiconductor process tools. This is achieved using semiconductor tool libraries that utilize a modular approach for designing and assembling each tool. For example, each semiconductor tool can be assembled from a main module, a substrate transfer module, a processing module, a substrate receiving module, a flow control module. A semiconductor tool library can include multiple different modules of each type. When a new tool is needed, a specific set of modules are selected from the library (e.g., based on the tool requirements) and assembled into a tool.

FIG. 8 is a process flowchart 800 illustrating various high-level stages in fabricating a semiconductor device using semiconductor tool libraries. Block 810 represents semiconductor device specifications.

Block 820 represents a semiconductor device fabrication process, which is developed based on the semiconductor device specification (in block 810). This process can include several different operations (block 822), which can have a particular sequence and require specific semiconductor process tools to perform each operation. Overall, the semiconductor device fabrication process determines the corresponding semiconductor processing line configuration (block 830), comprising specific configurations of all individual semiconductor process tools (block 832). These line/tool configurations are used to select (block 850) specific modules (block 842) from a semiconductor tool library (block 840). These selected modules are then used to assemble (block 860) specific semiconductor process tools, e.g., by combining a main module, a substrate transfer module, a processing module, and a substrate receiving module. These assembled semiconductor process tools (block 872) form a semiconductor processing line (block 870), which is used to perform the planned semiconductor processing operations (block 880) and fabricate the semiconductor device (block 890) in accordance with the specification.

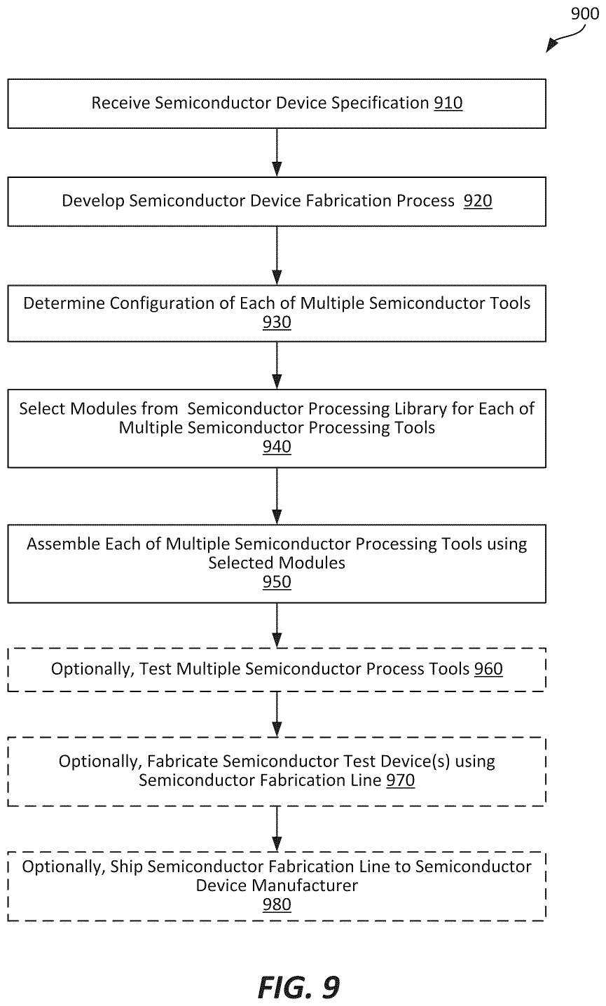

FIG. 9 is a process flowchart corresponding to method 900 of building a semiconductor processing line comprising semiconductor process tools 120 and using a semiconductor tool library. Method 900 may commence with (block 910) receiving a semiconductor device specification. Various examples of semiconductor devices (e.g., MEMS) are described below. The specification may include various structural and/or functional features of the device.

Method 900 may proceed with (block 920) developing a semiconductor device fabrication process, based on the semiconductor device specification. The process can include a sequence of operations specifically tailored to achieve various structural and functional requirements of the device. A couple of examples are shown and described above with reference to FIGS. 5A and 5B.

Method 900 may proceed with (block 930) determining a configuration of each of the semiconductor process tools, based on a corresponding one of semiconductor operations, selected for fabrication of a semiconductor device. For example, each operation may have a corresponding process tool. It should be noted that, in some examples, the same process tool can be used to perform multiple operations in the same process.

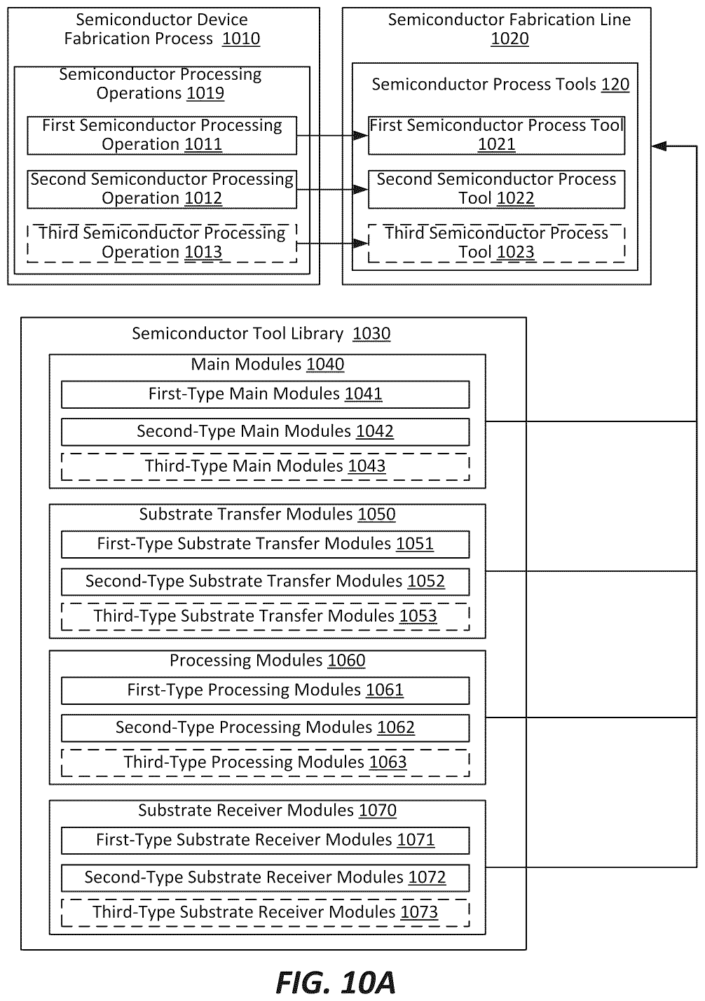

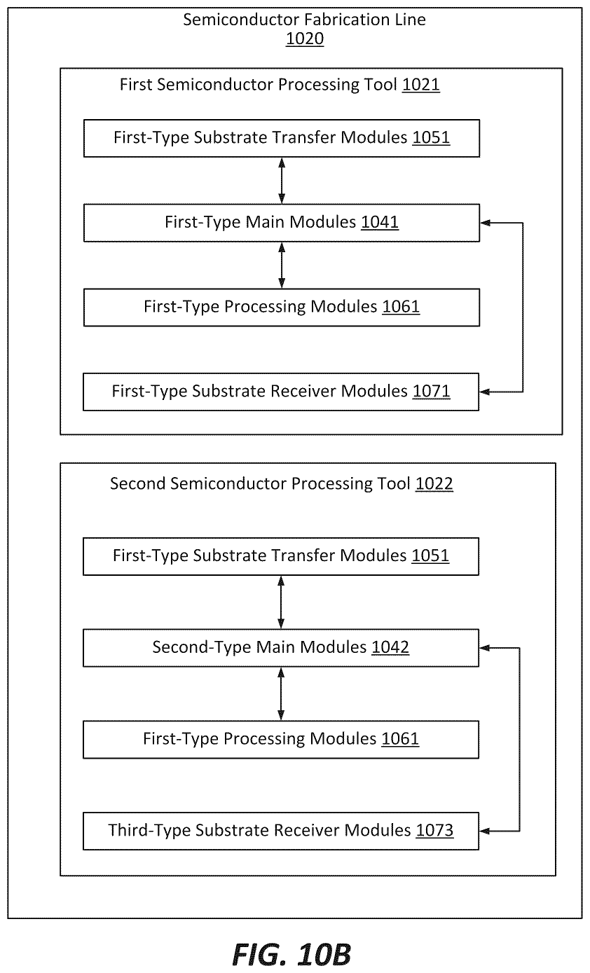

Method 900 may proceed with (block 940) selecting, from a semiconductor tool library, one of the main modules, one of the substrate transfer modules, one of the processing modules, and one of the substrate receiver modules for each of the semiconductor process tools and based on the configuration of each of the semiconductor process tools. This step is illustrated in FIG. 10A showing semiconductor device fabrication process 1010, semiconductor fabrication line 1020, and semiconductor tool library 1030. As noted above, semiconductor device fabrication process 1010 is developed to include various semiconductor processing operations 1019, schematically shown as first semiconductor processing operation 1011, second semiconductor processing operation 1012, and (optionally) third semiconductor processing operation 1013. In general, semiconductor device fabrication process 1010 may include two or more semiconductor processing operations 1019. The type and the number of these semiconductor processing operations 1019 depend on the structural and functional requirements of the semiconductor device specification. It should be noted that each one of semiconductor processing operations 1019 corresponds to a semiconductor process tool. A collection of these semiconductor process tools 120 form semiconductor fabrication line 1020. In some examples, semiconductor process tools 120 are arranged into one or more integrated benchtop semiconductor process cells 100, which then form semiconductor fabrication line 1020. Various examples of integrated benchtop semiconductor process cells 100 are described above with reference to FIG. 1A-1D. Some aspects of semiconductor fabrication lines, which may be also referred to as cell-based semiconductor fabs, are described above with reference to FIGS. 3-4.

For example, FIG. 10A illustrates first semiconductor processing operation 1011 corresponding to first semiconductor process tool 1021, second semiconductor processing operation 1012—second semiconductor process tool 1022, and (optionally) third semiconductor processing operation 1013—third semiconductor process tool 1023. In some examples, the same semiconductor process tool can be used to perform two or more operations in semiconductor device fabrication process 1010. In other words, the number of semiconductor process tools is the same or smaller than the number of semiconductor processing operations.

Referring to FIG. 10A, each semiconductor process tool is formed using different modules, such as one of main modules 1040, one of substrate transfer modules 1050, one of processing modules 1060, and/or one of substrate receiver modules 1070. Each module type may have different sub-types, e.g., main modules 1040 comprises first-type main modules 1041, second-type main modules 1042, and/or third-type main modules 1043. Similarly, transfer modules 1050 comprises first-type transfer modules 1051, second-type transfer modules 1052, and/or third-type transfer modules 1053. Processing modules 1060 comprises first-type processing modules 1061, second-type processing modules 1062, and/or third-type processing modules 1063. Finally, substrate receiver modules 1070 comprises first-type substrate receiver modules 1071, second-type substrate receiver modules 1072, and/or third-type substrate receiver modules 1073. All modules (of different types and different subtypes) form semiconductor tool library 1030.

It should be noted that each sub-type of main modules 1040 can be connected to each sub-type of any other of the three types. For example, any one of main modules 1040 can be connected to any one of substrate transfer modules 1050, to any one of processing modules 1060, and separately to any one of substrate receiver modules 1070. This provides many different options for semiconductor process tools 120. For example, having two different sub-types in each of the four types of modules (i.e., main modules 1040, substrate transfer modules 1050, processing modules 1060, and substrate receiver modules 1070) can theoretically produce 16 unique examples of semiconductor process tools 120. Increasing the number of subtypes (in each of four types) to 10 increases the number of unique tool examples to 10,000 (or 10⁴). These examples illustrate the flexibility of the modular approach and the benefits of semiconductor tool library 1030. This mix-and-match approach is illustrated in FIG. 10B.

It should be noted that the ability to connect each sub-type of main modules 1040 can be connected to each sub-type of any other of the three types is provided by specific interfaces used on each module as shown in FIG. 11. For example, any one of substrate transfer modules 1110 comprises substrate-transfer-to-main interface 1112, which is configured to connect to main-to-substrate-transfer interface 1122 of any one of main modules 1120. Similarly, any one of processing modules 1130 comprises processing-to-main interface 1132, which is configured to connect to main-to-processing interface 1124 of any one of main modules 1120. Finally, any one of substrate receiver modules 1140 comprises substrate-receiver-to-main interface 1142, which is configured to connect to main-to-substrate-receiver interface 1126 of any one of main modules 1120.

Returning to FIG. 9, method 900 proceeds with (block 950) assembling each of the semiconductor process tools by connecting the one of main modules to the one of substrate transfer modules and the one of processing modules and also by positioning the one of substrate receiver modules inside the one of main modules, wherein the semiconductor process tools form the semiconductor fabrication line. This assembly includes interconnecting various interfaces, e.g., is schematically shown in FIG. 11.

In some examples, (block 950) assembling each of semiconductor process tools 120 comprises reconfiguring at least one of semiconductor process tools 120 by disconnecting the one of main modules 1120 from at least the one of processing modules 1130 and reconnecting a different one of processing modules 1130 to the one of main modules 1120. This reconfiguration allows changing the functionality of semiconductor process tools 120. In some examples, reconfiguring at least one of semiconductor process tools 120 also comprises disconnecting the one of main modules 1120 from at least the one of substrate receiver module 1140 and reconnecting a different one of substrate receiver module 1140 to the one of main modules 1120. In some examples, substrate receiver module 1140 support different operations of processing modules 1130, e.g., by heating/cooling the substrate, applying RF bias to the substrate, measuring different substrate parameters, and the like. In some examples, substrate receiver module 1140 is configured to lift semiconductor substrate 190 to an adjustable height in processing module 1130.

In some examples, (block 950) assembling each of semiconductor process tools 120 or, more generally, method 900 further comprises (a) positioning two or more of the semiconductor process tools 120 on benchtop 112 of tool compartment 110 (e.g., as shown in FIG. 1A), (b) fluidically coupling the two or more the semiconductor process tools 120 to one or more support modules 130 comprising one or more selected from the group consisting of a vacuum pump, a water chiller, and gas storage, and (c) connecting the two or more of the semiconductor process tools 120 to the external connections selected from the group consisting of an exhaust connection, an electrical power connection, and a compressed-gas connection.

In some examples, method 900 also involves various optional operations, such as (block 960) testing multiple semiconductor process tools, (block 970) fabricating one or more semiconductor test devices using the semiconductor fabrication line, and/or (block 980) shipping the semiconductor fabrication line to a semiconductor device manufacturer (e.g., who supplied the original device specification)

Overall, as shown in FIG. 10A, the semiconductor tool library comprises multiple types of the main modules, multiple types of the substrate transfer modules, multiple types of the processing modules, and multiple types of the substrate receiver modules from the semiconductor processing library for each of the semiconductor process tools and based on the configuration of each of the semiconductor process tools. As noted above, any one of the main modules in the semiconductor tool library is configured to connect to any one of the substrate transfer modules and to any one of the processing modules and is further configured to receive any one of the substrate receiver modules.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present examples are to be considered illustrative and not restrictive.

1. An integrated benchtop semiconductor process cell for processing a semiconductor substrate, the integrated benchtop semiconductor process cell comprising:
a tool compartment, comprising a benchtop;
one or more semiconductor process tools, positioned in the tool compartment on the benchtop, wherein each of the one or more semiconductor process tools is selected from the group consisting of a lithography tool, a photoresist process tool, a thermal process tool, a chemical vapor deposition tool, a sputtering tool, an atomic layer deposition tool, an ion-etching tool, and a wafer cutting tool;
one or more support modules, fluidically coupled to each of the one or more semiconductor process tools and all positioned under the benchtop, wherein the one or more support modules comprise one or more selected from the group consisting of a vacuum pump, a water chiller, and a gas storage; and
external connections selected from the group consisting of an exhaust connection, an electrical power connection, and a compressed-gas connection, wherein a combination of only three or less of the external connections and the one or more support modules is configured to support all operations of each of the one or more semiconductor process tools of the integrated benchtop semiconductor process cell.

2. The integrated benchtop semiconductor process cell of claim 1, wherein the integrated benchtop semiconductor process cell has a footprint of less than 3 square meters.

3-6. (canceled)

7. The integrated benchtop semiconductor process cell of claim 1, wherein the integrated benchtop semiconductor process cell has a maximum power consumption of less than 100 kW.

8. The integrated benchtop semiconductor process cell of claim 1, further comprising a plurality of controllers, positioned proximate to the one or more semiconductor process tools, wherein the plurality of controllers comprises one or more mass flow controllers fluidically coupling the one or more semiconductor process tools to the gas storage.

9-10. (canceled)

11. The integrated benchtop semiconductor process cell of claim 8, wherein some of the plurality of controllers are positioned above the benchtop and the semiconductor process tools.

12. (canceled)

13. The integrated benchtop semiconductor process cell of claim 1, wherein the tool compartment comprises a front opening for accessing the benchtop.

14. The integrated benchtop semiconductor process cell of claim 1, wherein:
the tool compartment is enclosed and comprises a front panel comprising a plurality of gloves, isolating the benchtop from environment, and
the integrated benchtop semiconductor process cell comprises a substrate transfer module for isolated transfer between the tool compartment and environment.

15. The integrated benchtop semiconductor process cell of claim 1, wherein the semiconductor substrate has a diameter less than 100 millimeters.

16. The integrated benchtop semiconductor process cell of claim 1, wherein:
each of the semiconductor process tools comprises a main module, a substrate transfer module, a processing module, and a substrate receiver module,
the main module is sealably and removably coupled to each of the substrate transfer module, the processing module, and the substrate receiver module,
the substrate transfer module is configured to protrude into the main module and position of the semiconductor substrate onto the substrate receiver module; and
the substrate receiver module is configured to lift the semiconductor substrate to an adjustable height in the processing module.

17. The integrated benchtop semiconductor process cell of claim 16, wherein:
the main module of each of the semiconductor process tools is same, and
the processing module of at least of the semiconductor process tools is different.

18. The integrated benchtop semiconductor process cell of claim 16, wherein the substrate receiver module is configured to perform at least one function selected from the group consisting of (a) applying heating or cooling to the semiconductor substrate, (b) flowing gas to a backside of the semiconductor substrate, (c) and applying RF bias to the semiconductor substrate, and (d) measuring parameters on or near the semiconductor substrate.

19-21. (canceled)

22. A cell-based semiconductor fab comprising:
an integrated benchtop semiconductor process cell; and
an additional integrated benchtop semiconductor process cell; wherein:
each of the integrated benchtop semiconductor process cell and the additional integrated benchtop semiconductor process cell comprises:
a tool compartment, comprising a benchtop;
one or more semiconductor process tools, positioned in the tool compartment on the benchtop,
wherein each of the one or more semiconductor process tools is selected from the group consisting of a lithography tool, a photoresist process tool, a thermal process tool, a chemical vapor deposition tool, a sputtering tool, an atomic layer deposition tool, an ion-etching tool, and a wafer cutting tool; and
one or more support modules, fluidically coupled to each of the one or more semiconductor process tools and positioned under the benchtop,
wherein the one or more support modules comprise one or more selected from the group consisting of a vacuum pump, a water chiller, and a gas storage, and
at least one of the one or more support modules of the integrated benchtop semiconductor process cell is fluidically coupled to at least one of the one or more semiconductor process tools of the additional integrated benchtop semiconductor process cell.

23. (canceled)

24. A method of building a semiconductor fabrication line comprising semiconductor process tools and using a semiconductor tool library, the method comprising:
determining a configuration of each of the semiconductor process tools, based on a corresponding one of semiconductor operations, selected for fabrication of a semiconductor device,
selecting, from the semiconductor tool library, one of main modules, one of substrate transfer modules, one of processing modules, and one of substrate receiver modules for each of the semiconductor process tools and based on the configuration of each of the semiconductor process tools; and
assembling each of the semiconductor process tools by connecting the one of main modules to the one of substrate transfer modules and the one of processing modules and also by positioning the one of substrate receiver modules inside the one of main modules, wherein the semiconductor process tools form the semiconductor fabrication line.

25. The method of claim 24, wherein the semiconductor operations are selected from the group consisting of lithography, photoresist processing, thermal processing, chemical vapor deposition, sputtering, atomic layer deposition, ion-etching, and wafer cutting.

26. The method of claim 24, wherein connecting the one of main modules to the one of substrate transfer modules and the one of processing modules comprises forming a sealed temporary connection between the one of main modules and each of the one of substrate transfer modules and the one of processing modules comprises.

27. The method of claim 24, wherein, in the semiconductor tool library, each of the main modules is configured to connect to any one of the substrate transfer modules and, separately, to any one of the processing modules.

28. The method of claim 24, wherein different ones of the processing modules are configured to perform different ones of the semiconductor operations.

29. (canceled)

30. The method of claim 24, wherein:
the semiconductor fabrication line comprises an integrated benchtop semiconductor process cell comprising a tool compartment, one or more support modules, and external connections, and
the method further comprises (a) positioning two or more of the semiconductor process tools on a benchtop of the tool compartment, (b) fluidically coupling the two or more the semiconductor process tools to the one or more support modules comprising one or more selected from the group consisting of a vacuum pump, a water chiller, and gas storage, and (c) connecting the two or more of the semiconductor process tools to the external connections selected from the group consisting of an exhaust connection, an electrical power connection, and a compressed-gas connection.

31. The method of claim 24, wherein:
the semiconductor tool library comprises multiple types of the main modules, multiple types of the substrate transfer modules, multiple types of the processing modules, and multiple types of the substrate receiver modules from the semiconductor processing library for each of the semiconductor process tools and based on the configuration of each of the semiconductor process tools, and
any one of the main modules in the semiconductor tool library is configured to connect to any one of the substrate transfer modules and to any one of the processing modules and is further configured to receive any one of the substrate receiver modules.

32. The method of claim 24, further comprising reconfiguring at least one of the semiconductor process tools by disconnecting the one of main modules from at least the one of processing modules and reconnecting a different one of processing modules to the one of main modules.

33-41. (canceled)
